(19) United States
(12) Patent Application Publication
(10) Pub. No.: US 2025/0372568 A1
(43) Pub. Date: Dec. 4, 2025

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventors: HYUNSOO CHUNG, Suwon-si (KR); KWANGSOO KIM, Suwon-si (KR)

(21) Appl. No.: 19/028,805

(22) Filed: Jan. 17, 2025

(30) Foreign Application Priority Data
Apr. 1, 2024 (KR) 10-2024-0044117

(51) Int. Cl. H01L 23/00; H01L 21/56; H01L 21/683; H01L 23/31; H01L 25/065; H01L 25/10; H10B 80/00

(52) U.S. Cl. CPC H01L 24/48; H01L 21/563; H01L 21/6835; H01L 23/3135; H01L 24/13; H01L 24/16; H01L 24/73; H01L 25/0657; H01L 25/105; H01L 24/32; H01L 2224/13016; H01L 2224/13023; H01L 2224/16225; H01L 2224/32145; H01L 2224/48225; H01L 2224/73253; H01L 2224/73265; H01L 2225/0651; H01L 2225/06517; H01L 2225/06562; H01L 2225/1023; H01L 2225/1052; H01L 2225/1058; H01L 2924/3512; H10B 80/00

(57) ABSTRACT

A semiconductor package includes a package substrate, and a first plurality of semiconductor chips that is disposed on the package substrate and that includes at least two semiconductor chips. A semiconductor chip of the first plurality of semiconductor chips disposed closest to the package substrate may be connected to the package substrate by a bump, and a semiconductor chip of the first plurality of semiconductor chips disposed farthest from the package substrate may be connected to the package substrate by a wire.

### CROSS-REFERENCE TO RELATED APPLICATION

This application claims the benefit of Korean Patent Application No. 10-2024-0044117, filed on Apr. 1, 2024, in the Korean Intellectual Property Office, the entire disclosure of which is incorporated herein by reference for all purposes.

### BACKGROUND

### 1. Field of the Invention

The present invention relates to a semiconductor package and a method of manufacturing the semiconductor package.

### 2. Description of the Related Art

With the trend toward electronic devices having a reduced size and increased performance, miniaturization and high performance have also been desired in the field of semiconductor packages. To realize miniaturization, weight reduction, high performance, high capacity, and high reliability of a semiconductor package, semiconductor packages having a structure in which semiconductor chips are stacked in multiple stages have been under development.

### SUMMARY

An aspect of the present invention is to provide a semiconductor package and a method of manufacturing the semiconductor package that may satisfy requirements for high performance and high capacity while reducing a possibility of damage during the manufacturing process of a semiconductor package including a vertical interconnector.

According to an aspect, there is provided a semiconductor package includes a package substrate, and a first plurality of semiconductor chips disposed on the package substrate. A closest semiconductor chip of the first plurality of semiconductor chips to the package substrate is connected to the package substrate by a first bump, and a farthest semiconductor chip of the first plurality of semiconductor chips from the package substrate is connected to the package substrate by a first wire. The closest and farthest semiconductor chips perform the same function and have the same size as each other.

According to another aspect, there is provided a method of manufacturing a semiconductor package, the method includes forming a second sub-package including a second plurality of semiconductor chips on a carrier substrate; forming a first sub-package including a first plurality of semiconductor chips on the second sub-package; forming a package substrate on the first sub-package; and separating the carrier substrate from the second sub-package. A closest semiconductor chip of the first plurality of semiconductor chips to the package substrate is connected to the package substrate by a first bump. A farthest semiconductor chip of the first plurality of semiconductor chips from the package substrate is connected to the package substrate by a first wire. A closest semiconductor chip of the second plurality of semiconductor chips to the package substrate is connected to the package substrate by a second bump and a second wire. A farthest semiconductor chip of the second plurality of semiconductor chips from the package substrate is connected to the package substrate by a plurality of third wires.

According to yet another aspect, there is provided a semiconductor package comprises a package substrate; a first plurality of semiconductor chips disposed on the package substrate; and a second plurality of semiconductor chips disposed on the first plurality of semiconductor chips. The second plurality of semiconductor chips includes a first semiconductor chip. The semiconductor package further comprises a first molding layer disposed on the package substrate; a second molding layer disposed on the first molding layer; a first bump formed on the first semiconductor chip; and a first wire formed on the package substrate. The second molding layer surrounds the second plurality of semiconductor chips, and the first molding layer surrounds the first plurality of semiconductor chips. The first bump and the first wire are in contact with each other, and an interface between the first bump and the first wire is aligned to an interface between the first and second molding layers.

Additional aspects of the invention will be set forth in part in the description which follows and, in part, will be apparent from the description, or may be learned by practice of the disclosure.

According to embodiments, a semiconductor package and a method of manufacturing the semiconductor package that features a multi-layer molding structure to minimize an overhang issue during the manufacturing process. Accordingly, it may ensure a high-quality molding process and prevent die cracks when an interconnector is formed.

In addition, according to embodiments, a semiconductor package and a method of manufacturing the semiconductor package may use a bump as an interconnector, or use a combination of a bump and a wire as interconnectors, or use a plurality of wires as interconnectors, to maintain a length of a single wire to be ½ or less of a total height of a semiconductor package, thereby preventing wire sweeping.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIGS. 1 to 5 are diagrams illustrating examples of a semiconductor package including four semiconductor chips according to various embodiments;

FIG. 1A is a partially enlarged view of region “R1” of FIG. 1.

FIGS. 6 to 8 are diagrams illustrating examples of a semiconductor package including six semiconductor chips according to various embodiments;

FIGS. 9 to 11 are diagrams illustrating examples of a semiconductor package including eight semiconductor chips according to various embodiments;

FIG. 12 is a flowchart illustrating a method of manufacturing a semiconductor package according to an embodiment;

FIGS. 13A to 13G are diagrams illustrating a method of manufacturing a semiconductor package including four semiconductor chips according to an embodiment; and

FIGS. 14A to 14G are diagrams illustrating a method of manufacturing a semiconductor package including eight semiconductor chips according to an embodiment.

### DETAILED DESCRIPTION OF EXAMPLE EMBODIMENTS

Hereinafter, embodiments will be described in detail with reference to the accompanying drawings. However, various alterations and modifications may be made to the embodiments. Here, the embodiments are not construed to limit the invention. The embodiments should be understood to include all changes, equivalents, and replacements made thereto within the spirit and scope of the invention.

The terminology used herein is for the purpose of describing particular embodiments only and is not construed to limit the invention. The singular forms “a”, “an”, and “the” are intended to include the plural forms as well, as can be seen, for example, in the drawings. Thus, the description of a single item that is provided in plural should be understood to be applicable to the remaining plurality of items unless the context clearly indicates otherwise.

It will be further understood that the terms “comprises” when used herein, specify the presence of stated features, integers, steps, operations, elements, and/or components, but do not preclude the presence or addition of one or more other features, integers, steps, operations, elements, components and/or groups thereof.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Unless otherwise defined, all terms including technical and scientific terms used herein have the same meaning as commonly understood by one of ordinary skill in the art to which embodiments belong. It will be further understood that terms, such as those defined in commonly used dictionaries, should be interpreted as having a meaning that is consistent with their meaning in the context of the relevant art and/or the present disclosure, and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions may be omitted.

In addition, terms such as first, second, A, B, (a), (b), and the like may be used to describe components of the embodiments. Each of these terms is not used to define an essence, order or sequence of a corresponding component but used merely to distinguish the corresponding component from other component(s). Terms that are not described using “first,” “second,” and the like, in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

It should be noted that if it is described in the specification that one component is “connected,” “coupled” or “joined” to another component, the former may be directly “connected,” “coupled,” and “joined” to the latter or “connected”, “coupled”, and “joined” to the latter via another component. In contrast, when an element is referred to as being “directly connected” or “directly coupled” to another element, or as “contacting” or “in contact with” another element (or using any form of the word “contact”), there are no intervening elements present at the point of contact.

A component, which has the same common function as the component included in one embodiment, may be described by using the same name in other embodiments, unless disclosed to the contrary. Accordingly, the description of such components in an embodiment may be applied to other embodiments, and repeated description may be omitted.

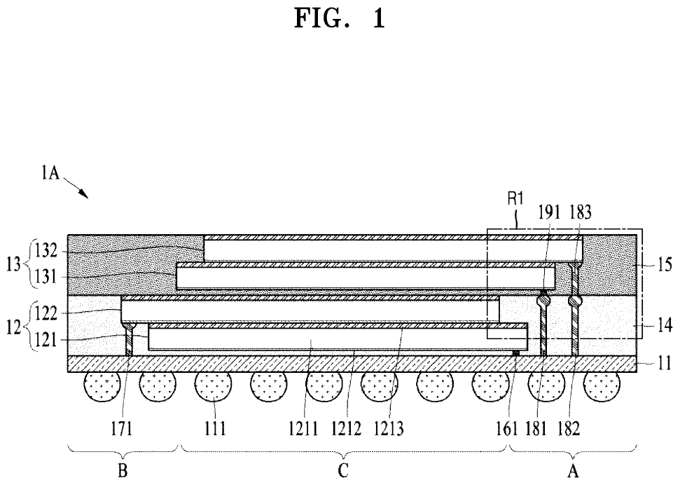

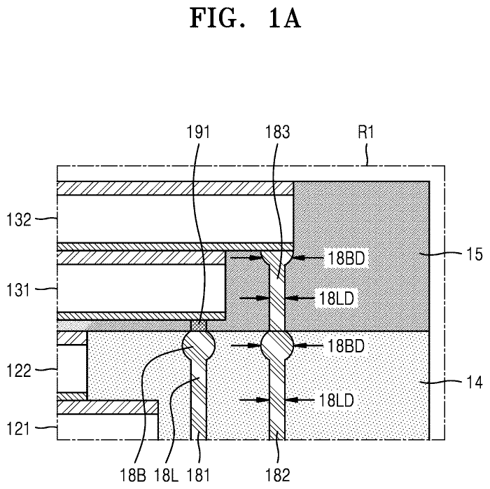

FIGS. 1 to 5 are diagrams illustrating examples of a semiconductor package including four semiconductor chips according to various embodiments. FIG. 1A is a partially enlarged view of region “R1” of FIG. 1. Referring to FIG. 1, a semiconductor package 1A according to an embodiment may include a redistribution layer 11, and a first semiconductor chip group 12 that is disposed on the redistribution layer 11 and that includes at least two semiconductor chips. A semiconductor chip of the first semiconductor chip group 12 disposed adjacent to the redistribution layer 11 may be directly electrically connected to the redistribution layer 11 by a bump, and another semiconductor chip of the first semiconductor chip group 12 disposed farthest from the redistribution layer 11 may be directly electrically connected to the redistribution layer 11 by a wire.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

The semiconductor package 1A may further include a second semiconductor chip group 13 that is disposed on the first semiconductor chip group 12 and that includes at least two semiconductor chips. A semiconductor chip of the second semiconductor chip group 13 disposed closest to the redistribution layer 11 may be directly electrically connected to the redistribution layer 11 by a bump and a wire, and another semiconductor chip of the second semiconductor chip group 13 disposed farthest from the redistribution layer 11 may be directly electrically connected to the redistribution layer 11 by a plurality of wires.

The semiconductor package 1A may further include a first molding member 14 surrounding the first semiconductor chip group 12, and a second molding member 15 surrounding the second semiconductor chip group 13. The first semiconductor chip group 12 may include a (1-1)-th semiconductor chip 121 and a (1-2)-th semiconductor chip 122 sequentially stacked on an area adjacent to the redistribution layer 11. The second semiconductor chip group 13 may include a (2-1)-th semiconductor chip 131 and a (2-2)-th semiconductor chip 132 sequentially stacked on an area adjacent to the first semiconductor chip group 12. For example, the (1-1)-th semiconductor chip 121 may be the next semiconductor chip to the redistribution layer 11 among all of the semiconductor chips in the semiconductor package 1A (i.e., all semiconductor chips of the first and second semiconductor chip groups 12 and 13). The (1-2)-th semiconductor chip 122 may be disposed two semiconductor chip above the redistribution layer 11. The (2-1)-th semiconductor chip 131 may be disposed three semiconductor chip above the redistribution layer 11. The (2-2)-th semiconductor chip 132 be disposed four semiconductor chip above redistribution layer 11.

The invention is not limited to the number of semiconductor chips, and each semiconductor chip group may include three semiconductor chips or four semiconductor chips, which will be described below. In addition, each semiconductor chip group may include at least five semiconductor chips, if necessary.

Each semiconductor chip may be disposed such that an active surface having a plurality of chip pads may face the redistribution layer 11.

In an example, the (1-1)-th semiconductor chip 121 of the first semiconductor chip group 12 may include a chip body 1211. The chip body 1211 may include an active surface 1212 which is a surface of the chip body 1211, and a die attach film (DAF) 1213 formed on another surface of the chip body 1211. The (1-1)-th semiconductor chip 121 may be disposed in the semiconductor package 1A such that the active surface 1212 of the semiconductor package 1A may face the redistribution layer 11. In addition, a chip pad may be formed on the active surface 1212.

The chip body 1211 may include a semiconductor substrate. The semiconductor substrate may include or be formed of, for example, silicon (Si). Depending on embodiments, the semiconductor substrate may include a semiconductor element such as germanium (Ge), or a compound semiconductor such as silicon carbide (SiC), gallium arsenide (GaAs), indium arsenide (InAs), and indium phosphide (InP). The chip body 1211 may include a semiconductor integrated circuit including a plurality of various types of discrete devices formed on the active surface 1212 that will be described below.

The plurality of chip pads may be embedded in each semiconductor chip, however the invention is not limited thereto. The chip pad may be electrically connected to the redistribution layer 11. The chip pad of the (1-1)-th semiconductor chip 121, which is closest to the redistribution layer 11, may be directly connected to the bump, and the redistribution layer 11 may be directly connected to the bump, thereby directly electrically connecting the redistribution layer 11 and the (1-1)-th semiconductor chip 121. The chip pad may include a conductive layer such as metal, metal nitride, conductive carbon, or a combination thereof. The chip pad may include, for example, Cu, Co, Al, Sn, Ni, Au, Ag, W, WN, Ti, TiN, Ta, TaN, Ru, Pt, or a combination thereof. The chip pad may be electrically connected to active/passive devices included in each of the plurality of semiconductor chips of the first and second semiconductor chip groups 12 and 13.

In addition, a semiconductor integrated circuit including a plurality of various types of discrete devices may be formed on or provided with the active surface 1212. The plurality of semiconductor chips may be various types of microelectronic devices The semiconductor chip may be a large-scale integration (LSI) device such as microprocessors, memory devices, and so on. The semiconductor chip may be a complementary metal-oxide-semiconductor (CMOS) device including a plurality of various types of discrete devices such as active devices and passive devices. The active devices may be metal-oxide-semiconductor field effect transistors (MOSFETs) Each of the plurality of discrete devices may be electrically separated from neighboring devices by an insulating film.

The above description may equally apply to the other semiconductor chips of the semiconductor package 1A.

In some embodiments, the semiconductor chips of the first and second semiconductor chip groups 12 and 13 may perform the same function and/or may have the same size as each other. For example, the semiconductor chips may be semiconductor memory chips that have the same storage capacity as each other. For example, the semiconductor chips may have the same size as each other in a plan view (as viewed along a direction which is perpendicular to an upper surface of the redistribution layer 11).

The DAF 1213 may include an organic material, for example, an epoxy resin. The DAF 1213 may function to maintain sufficient adhesion between the semiconductor chips. In addition, the DAF 1213 may function to electrically insulate the semiconductor chips from each other.

Though not shown in the drawings, the redistribution layer 11 may include a plurality of redistribution line patterns, a plurality of redistribution vias, and a redistribution insulating layer. In some embodiments, a plurality of redistribution insulating layers 186 may be stacked. The redistribution insulating layer may be formed of, for example, a photo imageable dielectric (PID) or a photosensitive polyimide (PSPI). The redistribution line patterns and the redistribution vias may be formed of, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or alloys thereof, but the invention is not limited thereto. In some embodiments, metals or metal alloys may be stacked on a seed layer including titanium, titanium nitride, or titanium tungsten, to form the redistribution line patterns and the redistribution vias.

The redistribution layer 11 may be substituted by a package substrate or an interposer. For example, the redistribution layer 11 may be a printed circuit board (PCB), a silicon interposer or combination thereof. The terms redistribution layer, package substrate, interposer and combination thereof may be collectively referred to as package substrate.

Each of the first molding member 14 and the second molding member 15 (also described as a first molding layer and a second molding layer) may include, for example, an epoxy mold compound (EMC). In some embodiments, a shape and dimensions (e.g., width and length) of the first molding member 14 and/or the second molding member 15 may be equal to those of the redistribution layer 11 in a plan view (as viewed along a direction which is perpendicular to an upper surface of the redistribution layer 11). For example, a horizontal width/length and a horizontal area of a molding member may be equal to a horizontal width/length and a horizontal area of the redistribution layer 11. For example, a side surface of the first molding member 14, a side surface of the second molding member 15, and a side surface of the redistribution layer 11 may be arranged in the same vertical plane. The side surfaces (or peripheral sidewalls) of the first molding member 14, the second molding member 15, and the redistribution layer 11 may be coplanar as viewed along a direction which is parallel to the upper surface of the redistribution layer 11. The first molding member 14 and the second molding member 15 may be formed of materials identical to or different from each other.

In addition, the semiconductor package 1A may include a connection terminal 111. The semiconductor package 1A may be electrically connected to another semiconductor package, another package substrate, a mainboard or a system board via the connection terminal 111. The connection terminal 111 is illustrated as a solder ball in the drawings, however the invention is not limited thereto. For example, the connection terminal 111 may be a solder bump, a grid array, a conductive tab, or the like. A plurality of connection terminals 111 may be formed on a bottom surface of the redistribution layer 11.

One end of an interconnector may be connected to a chip pad of a semiconductor chip, and another end of the interconnector may be connected to a redistribution layer. Accordingly, the semiconductor chip and the redistribution layer may be directly electrically connected to each other. For example, the semiconductor chip and the redistribution layer may be directly and/or indirectly connected to the interconnector. The interconnector may be or be formed by a bump and/or a wire. The bump may include or be a pillar bump. Each of the interconnectors may be in contact with a corresponding one of the semiconductor chips and/or the redistribution layers.

Though only a single connection is shown in the drawings for each of the semiconductor chips, a plurality of interconnectors may be formed on each of the semiconductor chips in the manner the interconnectors shown in the drawings are connected to a corresponding one of the semiconductor chips. For example, a plurality of bumps and/or wires may be disposed on each of the semiconductor chips to form a row (or column) or to form an array pattern, in a plan view (as viewed along a direction perpendicular to the active surface of the semiconductor chips). This modified arrangement of the plurality of interconnectors with respect to each of the semiconductor chips may be applicable to other embodiments described later.

A bonding wire may be used as an interconnector to electrically connect the semiconductor chip and the redistribution layer. For example, the semiconductor chip may be connected to a redistribution layer of the semiconductor package 1A in a wire bonding scheme. The bonding wire may include or be formed of gold (Au), copper (Cu), or the like. The bonding wire may extend in a direction perpendicular to the semiconductor chip and the redistribution layer, between the semiconductor chip and the redistribution layer. For example, through a wire bonding process, a vertical wire extending in one vertical direction may be disposed between the semiconductor chip and the redistribution layer. The vertical wire may vertically extend with a straight path between the semiconductor chip and the redistribution layer without loop-anchored shape. One end of the vertical wire may be directly connected to the semiconductor chip and another end of the vertical wire may be directly connected to the redistribution layer 11. Accordingly, the semiconductor chip and the redistribution layer 11 may be electrically connected.

For example, the wires may be vertical wires extending orthogonal from the active surfaces of the semiconductor chips or the redistribution layer. The vertical wires may extend directly away at a substantial right angle from the active surface of the semiconductor chips or the redistribution layer. Therefore, the electrical path between the substrate and the pad may be reduced compared to loop-anchored wires.

The vertical wire may be formed by, for example, a thermocompression wire bonding process, an ultrasonic wire bonding process, or a thermosonic wire bonding process. In a process of forming the first and second molding members 14 and 15, the vertical wire may retain its shape, resist from being swept, and remain in the vertical straight shape.

In an embodiment, the (1-1)-th semiconductor chip 121 may be connected to the redistribution layer 11 by a (1-1)-th bump 161 disposed within the first molding member 14, and the (1-2)-th semiconductor chip 122 may be connected to the redistribution layer 11 by a (1-1)-th wire 171 extending within the first molding member 14.

For example, one end of the (1-1)-th bump 161 may be directly connected to a chip pad of the (1-1)-th semiconductor chip 121, and another end of the (1-1)-th bump 161 may be directly connected to the redistribution layer 11. One end of the (1-1)-th wire 171 may be directly connected to a chip pad of the (1-2)-th semiconductor chip 122, and another end of the (1-1)-th wire 171 may be directly connected to the redistribution layer 11.

In an embodiment, the (2-1)-th semiconductor chip 131 may be directly electrically connected to the redistribution layer 11 by a (2-1)-th wire 181 extending within the first molding member 14 and a (2-1)-th bump 191 disposed within the second molding member 15. The (2-2)-th semiconductor chip 132 may be directly electrically connected to the redistribution layer 11 by a (2-2)-th wire 182 extending within the first molding member 14 and a (2-3)-th wire 183 extending within the second molding member 15.

The Interface between the first and second molding members 14 and 15 may be aligned to, at the same height level as, or coplanar with the Interface between the (2-1)-th wire 181 and the (2-1)-th bump 191. The Interface between the first and second molding members 14 and 15 may be aligned to, at the same height level as, or coplanar with the Interface between the (2-2)-th wire 182 and the (2-3)-th wire 183.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

For example, one end of the (2-1)-th wire 181 may be exposed to an outer surface of the first molding member 14, and another end of the (2-1)-th wire 181 may be directly connected to the redistribution layer 11. One end of the (2-1)-th bump 191 may be directly connected to a chip pad of the (2-1)-th semiconductor chip 131, and another end of the (2-1)-th bump 191 may be connected to the one end of the (2-1)-th wire 181.

One end of the (2-2)-th wire 182 may be exposed to the outer surface of the first molding member 14, and another end of the (2-2)-th wire 182 may be connected to the redistribution layer 11. One end of the (2-3)-th wire 183 may be connected to a chip pad of the (2-2)-th semiconductor chip 132, and another end of the (2-3)-th wire 183 may be connected to the one end of the (2-2)-th wire 182.

In an embodiment, the (1-1)-th semiconductor chip 121 and the (1-2)-th semiconductor chip 122 of the first semiconductor chip group 12 may be sequentially stacked in a staircase shape in a direction from a first side A of the semiconductor package 1A toward a second side B of the semiconductor package 1A. The (2-1)-th semiconductor chip 131 and the (2-2)-th semiconductor chip 132 of the second semiconductor chip group 13 may be sequentially stacked in a staircase shape in a direction from the second side B toward the first side A. The sides A and B may be opposite sides to each other.

Here, the (1-1)-th bump 161 may be disposed on the first side A, and the (1-1)-th wire 171 may be disposed on the second side B. The (2-1)-th wire 181, the (2-1)-th bump 191, the (2-2)-th wire 182, and the (2-3)-th wire 183 may be disposed on the first side A.

Referring to FIG. 1A, each of the wires may have an end portion 18B and an elongated portion 18L. The width 18BD of the end portion 18B may be greater than the width 18LD of the elongated portion 18L. The end portion 18B may be bonded onto the pad by compression bonding (TCB). The end portion 18B may have a spherical shape, a hemispherical shape or similar shapes thereof. The end portion 18B and the elongated portion 18L may be formed integrally. For example, the end portion 18B and the elongated portion 18L may be materially in continuity. For example, the plurality of wires may be formed sequentially in a one-by-one manner by using a capillary. For example, the wires may be formed of a material different from that of the bump.

As used herein, the terms “material continuity” and “materially in continuity” may refer to structures, patterns, and/or layers that are formed at the same time and of the same material, without a break in the continuity of the material of which they are formed. As one example, structures, patterns, and/or layers that are in “material continuity” or “materially in continuity” may be homogeneous monolithic structures.

Though not shown in the drawings, a portion of each of the chip pads may be exposed by a passivation layer (or layers). Each of the bumps may be connected to a corresponding one of the chip pads, and may be formed on the exposed portion of corresponding one of the chip pads. The passivation layer may be formed of electrically insulating material such as silicon oxide, silicon nitride, polyimide, etc. The passivation layer may be a composite layer of a plurality of insulating layers. The bump may not be materially in continuity. The bump may not be a materially homogenous single pattern. For example, the bump may include bump metallurgy (or under-bump metallurgy, UBM) structures. For example, the bump may be a stacked structure of a barrier layer, a seed layer and an electroplated bump pattern. The bump may be a combination of the barrier layer, the seed layer and the electroplated bump pattern. For example, the bumps may be simultaneously formed by the same process step (or the same series of process steps that are sequentially performed) on the pads.

In another embodiment, semiconductor chips of a first semiconductor chip group may be sequentially stacked in a staircase shape in a direction from the second side B of the semiconductor package toward the first side A of the semiconductor package. Semiconductor chips of a second semiconductor chip group may be sequentially stacked in a staircase shape in a direction from the first side A toward the second side B.

Hereinafter, for brevity and clarity, redundant descriptions that may be equally applicable among the technical concepts described above are omitted, and differences between other embodiments are described. Elements that are the same as or similar to those described in previous embodiments may not be redundantly described. The primary focus of the description may be on the differences from the previous embodiments.

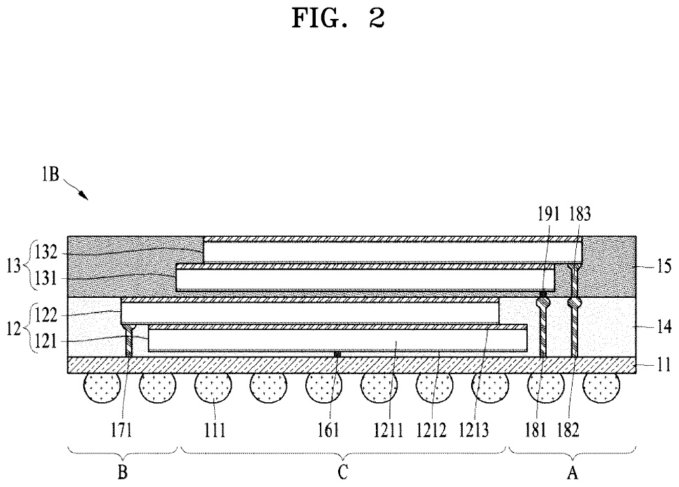

Referring to FIG. 2, a (1-1)-th bump 161 of a semiconductor package 1B according to an embodiment may be disposed in a portion C, which is between a first side A of the semiconductor package 1B and a second side B of the semiconductor package 1B. A (1-1)-th wire 171 may be disposed on the second side B of the semiconductor package 1B. A (2-1)-th wire 181, a (2-1)-th bump 191, a (2-2)-th wire 182, and a (2-3)-th wire 183 may be disposed on the first side A of the semiconductor package 1B.

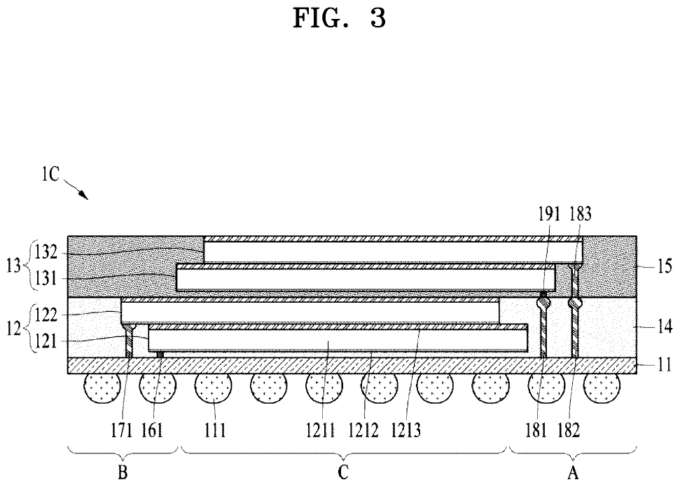

Referring to FIG. 3, a (1-1)-th bump 161 of a semiconductor package 1C according to an embodiment may be disposed on a second side B of the semiconductor package 1C, and a (1-1)-th wire 171 may also be disposed on the second side B. A (2-1)-th wire 181, a (2-1)-th bump 191, a (2-2)-th wire 182, and a (2-3)-th wire 183 may be disposed on first side A of the semiconductor package 1C.

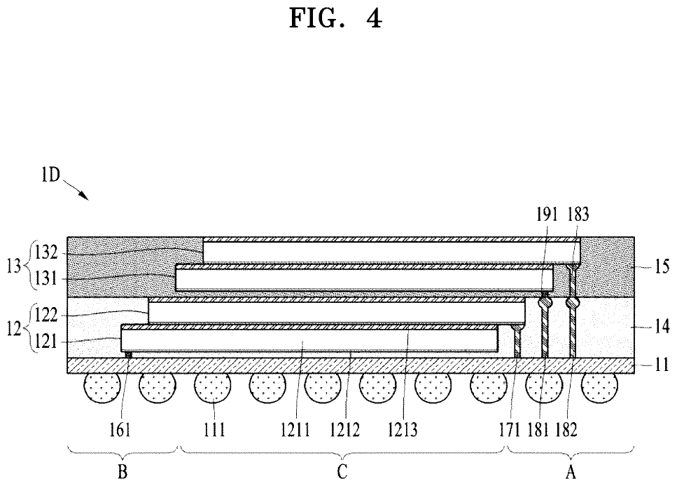

Referring to FIG. 4, semiconductor chips 121 and 122 of a first semiconductor chip group 12 and semiconductor chips 131 and 132 of a second semiconductor chip group 13 may all be sequentially stacked in a staircase shape in a direction from a second side B of a semiconductor package 1D toward the first side A of the semiconductor package 1D.

A (1-1)-th bump 161 of the semiconductor package 1D may be disposed on the second side B of the semiconductor package 1D, and a (1-1)-th wire 171 may be disposed on the first side A. A (2-1)-th wire 181, a (2-1)-th bump 191, a (2-2)-th wire 182, and a (2-3)-th wire 183 may be disposed on the first side A of the semiconductor package 1D.

In an alternative embodiment the (1-1)-th bump 161 of the semiconductor package 1D may be disposed on the first side A or in a portion C between the first side A and the second side B.

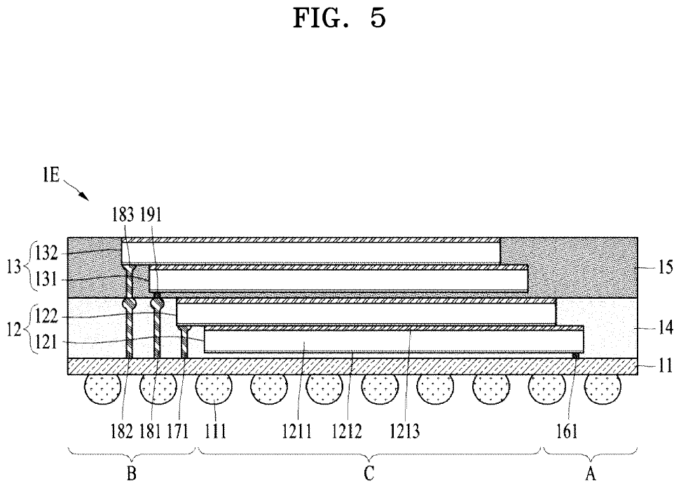

Referring to FIG. 5, semiconductor chips 121 and 122 of a first semiconductor chip group 12 and semiconductor chips 131 and 132 of a second semiconductor chip group 13 may all be sequentially stacked in a staircase shape in a direction from first side A of a semiconductor package 1E toward a second side B of the semiconductor package 1E.

A (1-1)-th bump 161 of the semiconductor package 1E may be disposed on the first side A of the semiconductor package 1E, and a (1-1)-th wire 171 may be disposed on the second side B. A (2-1)-th wire 181, a (2-1)-th bump 191, a (2-2)-th wire 182, and a (2-3)-th wire 183 may be disposed on the second side B of the semiconductor package 1E.

In an alternative embodiment, the (1-1)-th bump 161 of the semiconductor package 1E may be disposed on the second side B or in a portion C between the first side A and the second side B.

In another alternative embodiment, the first molding member 14 and the second molding member 15 may each include (or surround) a single semiconductor chip. In this example, first and second semiconductor chips may be included in or surrounded by the first molding member 14 and the second molding member 15, respectively. The first semiconductor chip may be directly electrically connected to a redistribution layer by a bump, and the second semiconductor chip may be directly electrically connected to the redistribution layer by a bump and a vertical wire.

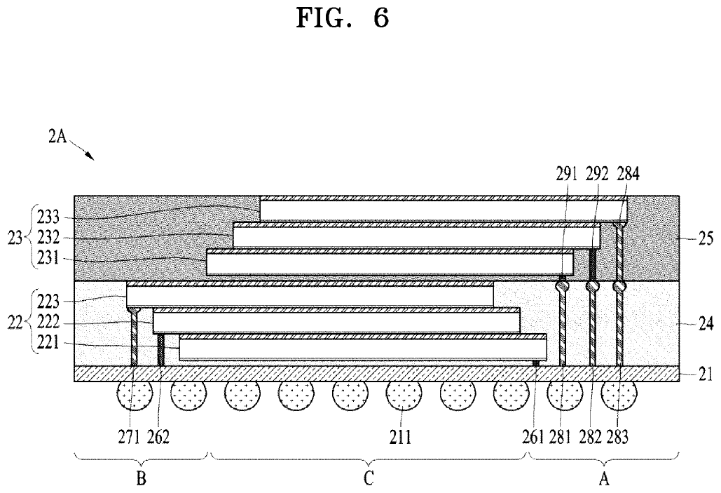

FIGS. 6 to 8 are diagrams illustrating examples of a semiconductor package including six semiconductor chips according to various embodiments.

Referring to FIG. 6, in an embodiment, a first semiconductor chip group 22 of a semiconductor package 2A may include a (1-1)-th semiconductor chip 221, a (1-2)-th semiconductor chip 222, and a (1-3)-th semiconductor chip 223 sequentially stacked on an area adjacent to a redistribution layer 21. A second semiconductor chip group 23 may include a (2-1)-th semiconductor chip 231, a (2-2)-th semiconductor chip 232, and a (2-3)-th semiconductor chip 233 sequentially stacked on an area adjacent to the first semiconductor chip group 22.

The semiconductor package 2A may further include a first molding member 24 surrounding the first semiconductor chip group 22, and a second molding member 25 surrounding the second semiconductor chip group 23.

The semiconductor package 2A may include a connection terminal 211. The semiconductor package 2A may be electrically connected to another semiconductor package, or a package board via the connection terminal 211.

The (1-1)-th semiconductor chip 221 to the (1-3)-th semiconductor chip 223 of the first semiconductor chip group 22 may be sequentially stacked in a staircase shape in a direction from first side A of the semiconductor package 2A toward a second side B of the semiconductor package 2A. The (2-1)-th semiconductor chip 231 to the (2-3)-th semiconductor chip 233 of the second semiconductor chip group 23 may be sequentially stacked in a staircase shape in a direction from the second side B toward the first side A.

The (1-1)-th semiconductor chip 221 may be connected to the redistribution layer 21 by a (1-1)-th bump 261 extending within the first molding member 24. The (1-2)-th semiconductor chip 222 may be connected to the redistribution layer 21 by a (1-2)-th bump 262 extending within the first molding member 24. The (1-3)-th semiconductor chip 223 may be connected to the redistribution layer 21 by a (1-1)-th wire 271. For example, the (1-2)-th bump 262 may be an elevated pillar bump. The height of the (1-2)-th bump 262 may be greater than the height of the (1-1)-th bump 261. For example, the elevated pillar bump may be formed by copper electroplating and solder reflow.

The (2-1)-th semiconductor chip 231 may be connected to the redistribution layer 21 by a (2-1)-th wire 281 extending within the first molding member 24 and a (2-1)-th bump 291 disposed within the second molding member 25. The (2-2)-th semiconductor chip 232 may be connected to the redistribution layer 21 by a (2-2)-th wire 282 extending within the first molding member 24 and a (2-2)-th bump 292 disposed extending within the second molding member 25. The (2-3)-th semiconductor chip 233 may be connected to the redistribution layer 21 by a (2-3)-th wire 283 extending within the first molding member 24 and a (2-4)-th wire 284 extending within the second molding member 25. For example, the (2-2)-th bump 292 may be an elevated pillar bump. The height of the (2-2)-th bump 292 may be greater than a height of the (2-1)-th bump 291.

The (1-1)-th bump 261 may be disposed on the first side A, and the (1-2)-th bump 262 and the (1-1)-th wire 271 may be disposed on the second side B. The (2-1)-th wire 281, the (2-1)-th bump 291, the (2-2)-th wire 282, the (2-2)-th bump 292, the (2-3)-th wire 283, and the (2-4)-th wire 284 may be disposed on the first side A.

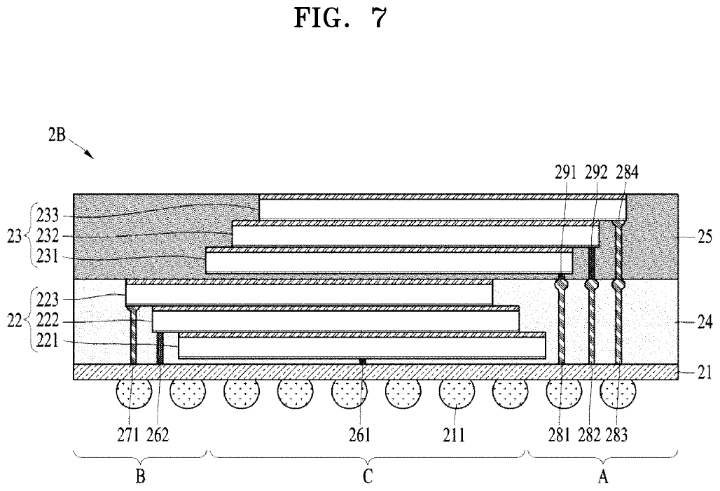

Referring to FIG. 7, in an embodiment, a (1-1)-th bump 261 of a semiconductor package 2B may be disposed in a portion C between first side A of the semiconductor package 2B and a second side B of the semiconductor package 2B, and a (1-2)-th bump 262 and a (1-1)-th wire 271 may be disposed on the second side B. A (2-1)-th wire 281, a (2-1)-th bump 291, a (2-2)-th wire 282, a (2-2)-th bump 292, a (2-3)-th wire 283, a (2-4)-th wire 284 may be disposed on the first side A.

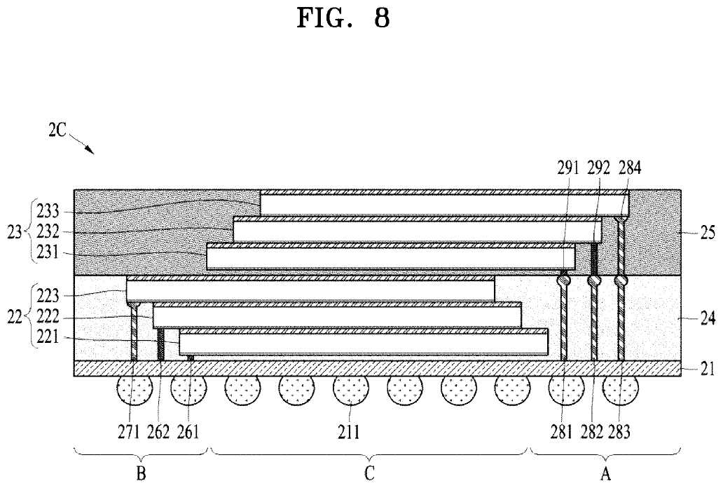

Referring to FIG. 8, in an embodiment, a (1-1)-th bump 261, a (1-2)-th bump 262, and a (1-1)-th wire 271 of a semiconductor package 2C may be disposed on a second side B of the semiconductor package 2C. A (2-1)-th wire 281, a (2-1)-th bump 291, a (2-2)-th wire 282, a (2-2)-th bump 292, a (2-3)-th wire 283, a (2-4)-th wire 284 may be disposed on first side A of the semiconductor package 2C.

Semiconductor chips of a first semiconductor chip group may be sequentially stacked in a staircase shape in a direction from the second side of a semiconductor package toward the first side of the semiconductor package. Semiconductor chips of a second semiconductor chip group may be sequentially stacked in a staircase shape in a direction from the first side toward the second side.

In an alternative embodiment, the semiconductor chips of the first semiconductor chip group and the semiconductor chips of the second semiconductor chip group may all be sequentially stacked in a staircase shape in the direction from the first side toward the second side or the direction from the second side toward the first side.

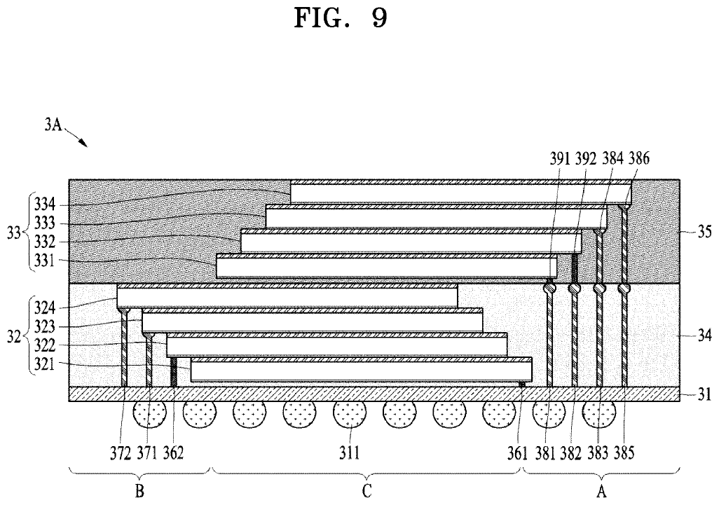

FIGS. 9 to 11 are diagrams illustrating examples of a semiconductor package including eight semiconductor chips according to various embodiments.

Referring to FIG. 9, in an embodiment, a first semiconductor chip group 32 of a semiconductor package 3A may include a (1-1)-th semiconductor chip 321, a (1-2)-th semiconductor chip 322, a (1-3)-th semiconductor chip 323, and a (1-4)-th semiconductor chip 324 that are sequentially stacked on an area adjacent to a redistribution layer 31. A second semiconductor chip group 33 may include a (2-1)-th semiconductor chip 331, a (2-2)-th semiconductor chip 332, a (2-3)-th semiconductor chip 333, and a (2-4)-th semiconductor chip 334 that are sequentially stacked on an area adjacent to the first semiconductor chip group 32.

The semiconductor package 3A may further include a first molding member 34 surrounding the first semiconductor chip group 32, and a second molding member 35 surrounding the second semiconductor chip group 33.

The semiconductor package 3A may include a connection terminal 311. The semiconductor package 3A may be electrically connected to another semiconductor package, or a package board via the connection terminal 311.

The (1-1)-th semiconductor chip 321 to the (1-4)-th semiconductor chip 324 of the first semiconductor chip group 32 may be sequentially stacked in a staircase shape in a direction from first side A of the semiconductor package 3A toward a second side B of the semiconductor package 3A. The (2-1)-th semiconductor chip 331 to the (2-4)-th semiconductor chip 334 of the second semiconductor chip group 33 may be sequentially stacked in a staircase shape in a direction from the second side B toward the first side A.

The (1-1)-th semiconductor chip 321 may be connected to the redistribution layer 31 by a (1-1)-th bump 361 disposed within the first molding member 34. The (1-2)-th semiconductor chip 322 may be connected to the redistribution layer 31 by a (1-2)-th bump 362 disposed within the first molding member 34. The (1-3)-th semiconductor chip 323 may be connected to the redistribution layer 31 by a (1-1)-th wire 371. The (1-4)-th semiconductor chip 324 may be connected to the redistribution layer 31 by a (1-2)-th wire 372.

The (2-1)-th semiconductor chip 331 may be connected to the redistribution layer 31 by a (2-1)-th wire 381 extending within the first molding member 34 and a (2-1)-th bump 391 disposed within the second molding member 35. The (2-2)-th semiconductor chip 332 may be connected to the redistribution layer 31 by a (2-2)-th wire 382 extending within the first molding member 34 and a (2-2)-th bump 392 disposed within the second molding member 35. The (2-3)-th semiconductor chip 333 may be connected to the redistribution layer 31 by a (2-3)-th wire 383 extending within the first molding member 34 and a (2-4)-th wire 384 extending within the second molding member 35. The (2-4)-th semiconductor chip 334 may be connected to the redistribution layer 31 by a (2-5)-th wire 385 extending within the first molding member 34 and a (2-6)-th wire 386 extending within the second molding member 35.

The (1-1)-th bump 361 may be disposed on the first side A, and the (1-2)-th bump 362, the (1-1)-th wire 371, and the (1-2)-th wire 372 may be disposed on the second side B. The (2-1)-th wire 381, the (2-1)-th bump 391, the (2-2)-th wire 382, the (2-2)-th bump 392, the (2-3)-th wire 383, the (2-4)-th wire 384, the (2-5)-th wire 385, and the (2-6)-th wire 386 may be disposed on the first side A.

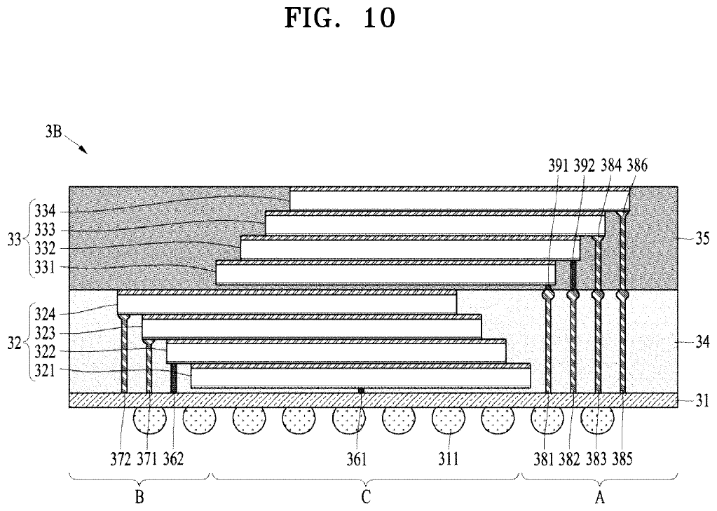

Referring to FIG. 10, in an embodiment, a (1-1)-th bump 361 of a semiconductor package 3B may be disposed in a portion C between first side A of the semiconductor package 3B and a second side B of the semiconductor package 3B, and a (1-2)-th bump 362, a (1-1)-th wire 371, and a (1-2)-th wire 372 may be disposed on the second side B. A (2-1)-th wire 381, a (2-1)-th bump 391, a (2-2)-th wire 382, a (2-2)-th bump 392, a (2-3)-th wire 383, a (2-4)-th wire 384, a (2-5)-th wire 385, and a (2-6)-th wire 386 may be disposed on the first side A.

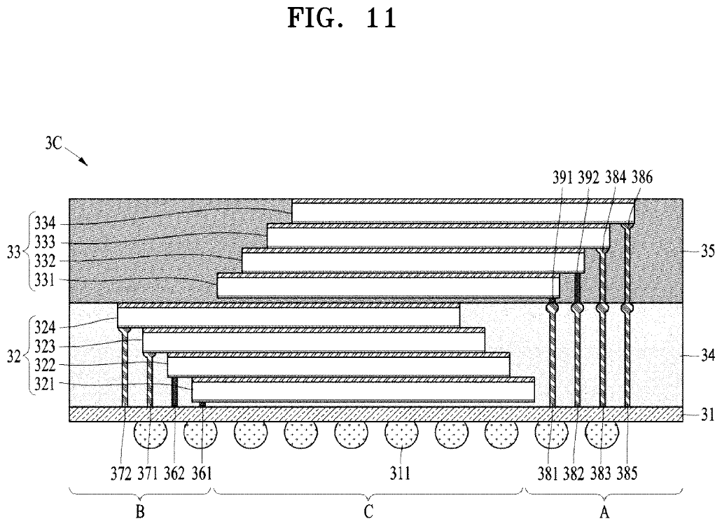

Referring to FIG. 11, in an embodiment, a (1-1)-th bump 261, a (1-2)-th bump 362, a (1-1)-th wire 371, and a (1-2)-th wire 372 of a semiconductor package 3C may be disposed on a second side B of the semiconductor package 3C. A (2-1)-th wire 381, a (2-1)-th bump 391, a (2-2)-th wire 382, a (2-2)-th bump 392, a (2-3)-th wire 383, a (2-4)-th wire 384, a (2-5)-th wire 385, and a (2-6)-th wire 386 may be disposed on first side A of the semiconductor package 3C.

Semiconductor chips of a first semiconductor chip group may be sequentially stacked in a staircase shape in a direction from the second side of a semiconductor package toward the second side of the semiconductor package. Semiconductor chips of a second semiconductor chip group may be sequentially stacked in a staircase shape in a direction from the first side toward the second side.

In an alternative embodiment, the semiconductor chips of the first semiconductor chip group and the semiconductor chips of the second semiconductor chip group may all be sequentially stacked in a staircase shape in the direction from the first side toward the second side or the direction from the second side toward the first side.

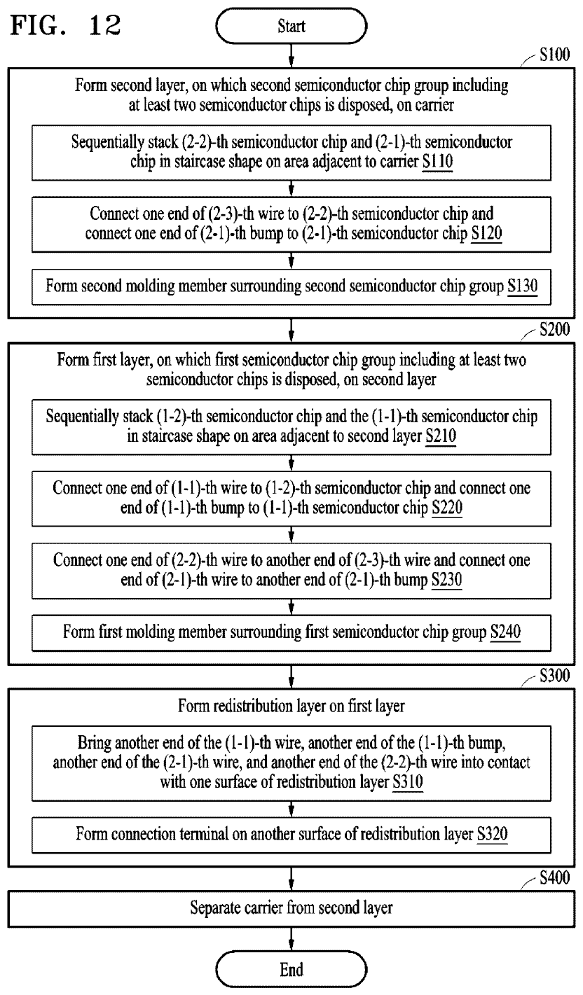

FIG. 12 is a flowchart illustrating a method of manufacturing a semiconductor package according to an embodiment.

Referring to FIG. 12, in an embodiment, the method of manufacturing the semiconductor package includes operation S100 of forming a second layer (also described as a second sub-package), on which a second semiconductor chip group including at least two semiconductor chips is disposed, on a carrier (also described as a carrier substrate). The method of manufacturing the semiconductor package further includes operation S200 of forming a first layer (also described as a second sub-package), on which a first semiconductor chip group including at least two semiconductor chips is disposed, on the second layer. The method of manufacturing the semiconductor package further includes operation S300 of forming a redistribution layer on the first layer, and operation S400 of separating the carrier from the second layer.

A semiconductor chip of the first semiconductor chip group disposed closest to the redistribution layer may be directly electrically connected to the redistribution layer by a bump. A semiconductor chip of the first semiconductor chip group disposed farthest from the redistribution layer may be connected to the redistribution layer by a wire. A semiconductor chip of the second semiconductor chip group disposed closest to the redistribution layer may be directly electrically connected to the redistribution layer by a bump and a wire. A semiconductor chip of the second semiconductor chip group disposed farthest from the redistribution layer may be connected to the redistribution layer by a plurality of wires.

In an embodiment, the second semiconductor chip group may include a (2-1)-th semiconductor chip and a (2-2)-th semiconductor chip.

Operation S100 may include operation S110 of sequentially stacking the (2-2)-th semiconductor chip and the (2-1)-th semiconductor chip in a staircase shape on an area adjacent to the carrier. The operation S100 may further include operation S120 of directly connecting one end of a (2-3)-th wire to the (2-2)-th semiconductor chip and connecting one end of a (2-1)-th bump to the (2-1)-th semiconductor chip. The operation S100 may further include operation S130 of forming a second molding member surrounding the second semiconductor chip group.

In operation S130, another end of the (2-3)-th wire and another end of the (2-1)-th bump may be exposed to an outer surface of the second molding member.

In an embodiment, the first semiconductor chip group may include a (1-1)-th semiconductor chip and a (1-2)-th semiconductor chip.

Operation S200 may include operation S210 of sequentially stacking the (1-2)-th semiconductor chip and the (1-1)-th semiconductor chip in a staircase shape on an area adjacent to the second layer. The operation S200 may further include operation S220 of connecting one end of a (1-1)-th wire to the (1-2)-th semiconductor chip and connecting one end of a (1-1)-th bump to the (1-1)-th semiconductor chip. The operation S100 may further include operation S230 of connecting one end of a (2-2)-th wire to the other end of the (2-3)-th wire and connecting one end of a (2-1)-th wire to the other end of the (2-1)-th bump. The operation S100 may further include operation S240 of forming a first molding member surrounding the first semiconductor chip group.

In an embodiment, in operation S240, another end of the (1-1)-th wire, another end of the (1-1)-th bump, another end of the (2-1)-th wire, and another end of the (2-2)-th wire may be exposed to an outer surface of the first molding member.

In an embodiment, operation S300 may include operation S310 of bringing the other end of the (1-1)-th wire, the other end of the (1-1)-th bump, the other end of the (2-1)-th wire, and the other end of the (2-2)-th wire into contact with one surface of the redistribution layer. The operation S300 may further include operation S320 of forming a connection terminal on another surface of the redistribution layer.

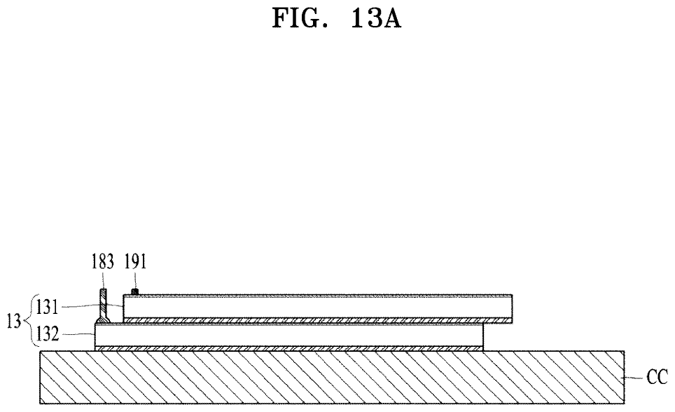

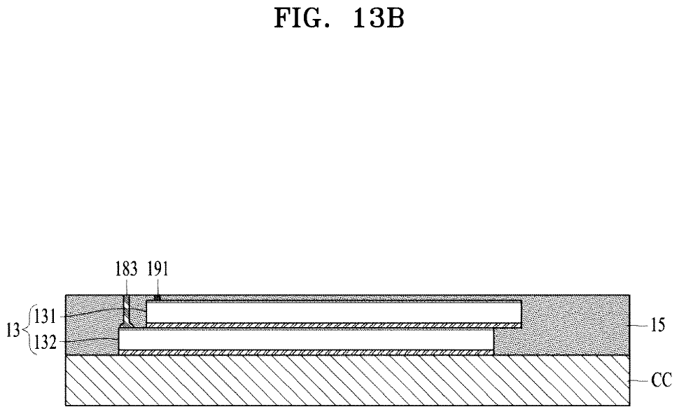

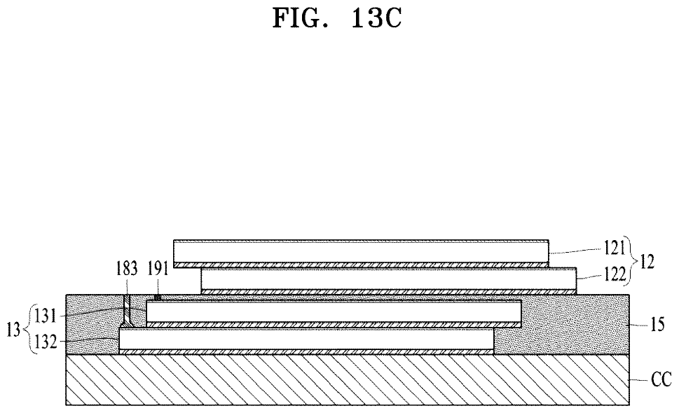

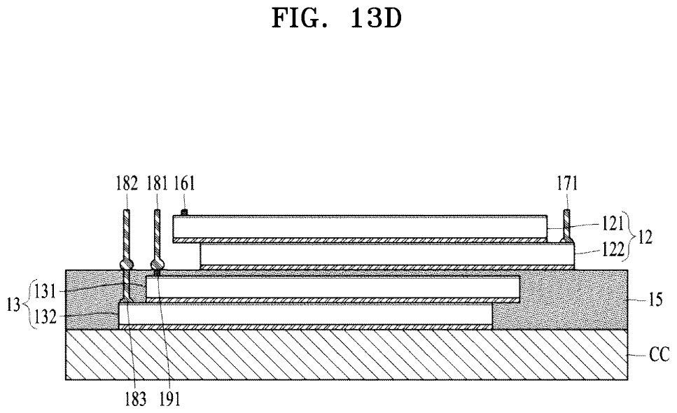

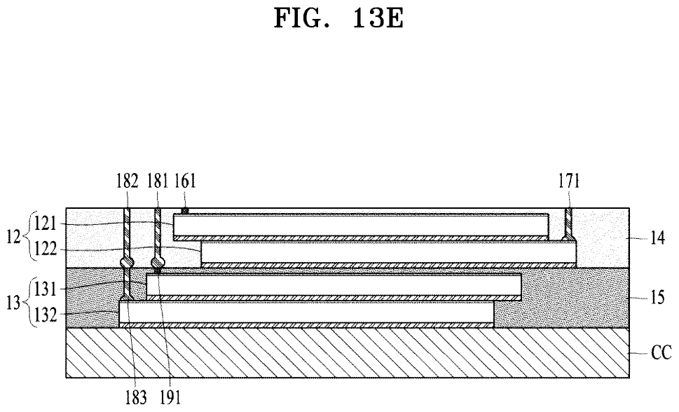

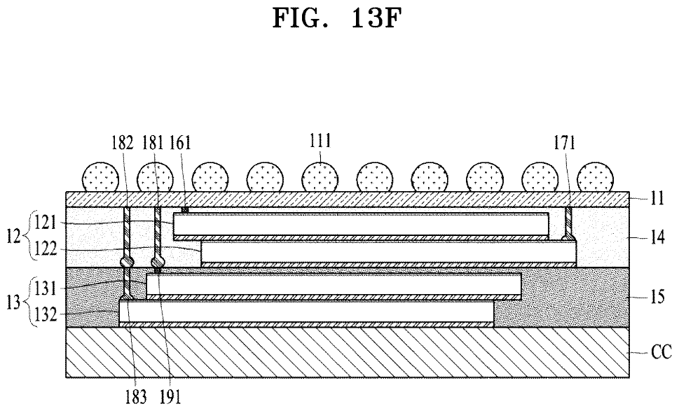

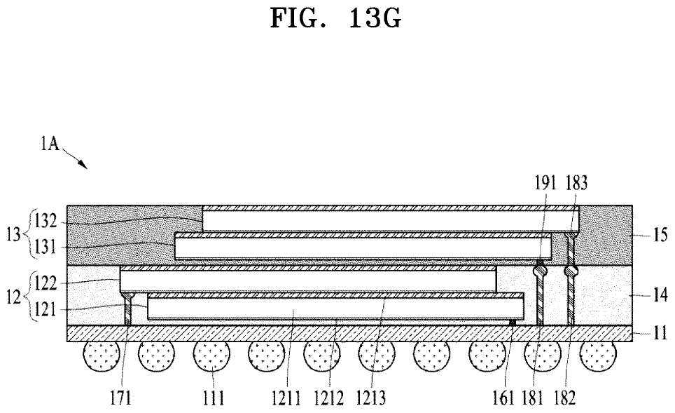

FIGS. 13A to 13G illustrate sequential operations of a method of manufacturing a semiconductor package including four semiconductor chips according to an embodiment.

Referring to FIG. 13A, a (2-2)-th semiconductor chip 132 and a (2-1)-th semiconductor chip 131 of a second semiconductor chip group 13 may be stacked in a staircase shape on a carrier CC. Subsequently, one end of a (2-3)-th wire 183 may be directly connected to the (2-2)-th semiconductor chip 132, and one end of a (2-1)-th bump 191 may be directly connected to the (2-1)-th semiconductor chip 131.

The bumps may be formed on chip pads of the upper semiconductor chip 131 (and other semiconductor chips). For example, the bump may be formed of or include a copper (Cu) material. Though not shown in the drawings, a barrier metal layer and a copper seed layer may be sequentially formed on the chip pads. The barrier metal layer and the copper seed layer may be parts of each bump in a final product. For example, patterned electroplating mask layer (not shown) may be formed over the copper seed layer, and an electroplating process may be performed to electroplate copper on exposed surfaces of the copper seed layer within openings through the bump patterned electroplating mask layer. The openings in the patterned electroplating mask layer may be arranged as one periodic two-dimensional array of openings having the same periodicity as a periodic two-dimensional array of bumps located on a respective semiconductor chip. Subsequently, the patterned electroplating mask layer may be removed. An etching process may be performed to remove portions of the seed layer and the barrier metal layer. Remaining portions of the barrier metal layer and the seed layer may constitute bumps. A thermal anneal process may be performed to induce grain growth in the remaining portions of the seed layer and the electroplated copper. In one embodiment, the bump may be configured for C2 bonding. In one embodiment, the bump may comprise a respective cylindrical portion protruding above the horizontal plane of the semiconductor chip.

Referring to FIG. 13B, a second molding member 15 surrounding the second semiconductor chip group 13 may be formed, such that another end of the (2-3)-th wire 183 and another end of the (2-1)-th bump 191 may be exposed to an outer surface of the second molding member 15.

Referring to FIG. 13C, a (1-2)-th semiconductor chip 122 and a (1-1)-th semiconductor chip 121 may be sequentially stacked in a staircase shape on an area adjacent to the second semiconductor chip group 13 and the second molding member 15. A first semiconductor chip group 12 including the (1-1)-th semiconductor chip 121 and the (1-2)-th semiconductor chip 122 may be formed on the second semiconductor chip group 13.

Referring to FIG. 13D, one end of a (1-1)-th wire 171 may be directly connected to the (1-2)-th semiconductor chip 122, and one end of a (1-1)-th bump 161 may be directly connected to the (1-1)-th semiconductor chip 121. One end of a (2-2)-th wire 182 may be directly connected to the other end of the (2-3)-th wire 183, and one end of a (2-1)-th wire 181 may be directly connected to the other end of the (2-1)-th bump 191.

Referring to FIG. 13E, a first molding member 14 surrounding the first semiconductor chip group 12 may be formed, such that another end of the (1-1)-th bump 161, another end of the (1-1)-th wire 171, another end of the (2-1)-th wire 181, and another end of the (2-2)-th wire 182 may be exposed to an outer surface of the first molding member 14.

Referring to FIG. 13F, the other end of the (1-1)-th bump 161, the other end of the (1-1)-th wire 171, the other end of the (2-1)-th wire 181, and the other end of the (2-2)-th wire 182 may be brought into contact with one surface of a redistribution layer 11. Subsequently, a connection terminal 111 may be formed on another surface of the redistribution layer 11.

Referring to FIG. 13G, the carrier CC may be separated from a semiconductor package 1A, and the semiconductor package 1A may be rotated such that the redistribution layer 11 may face downward.

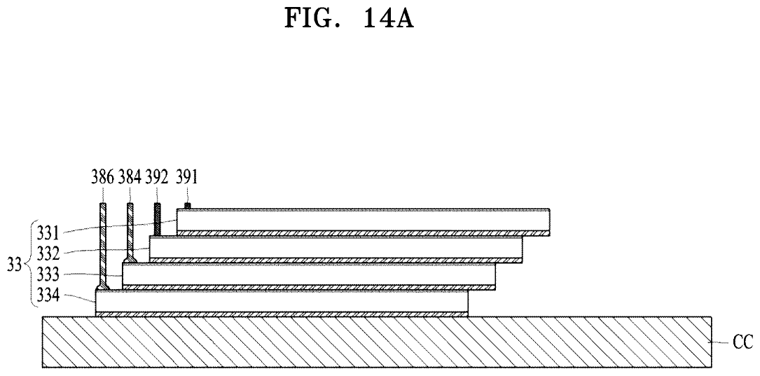

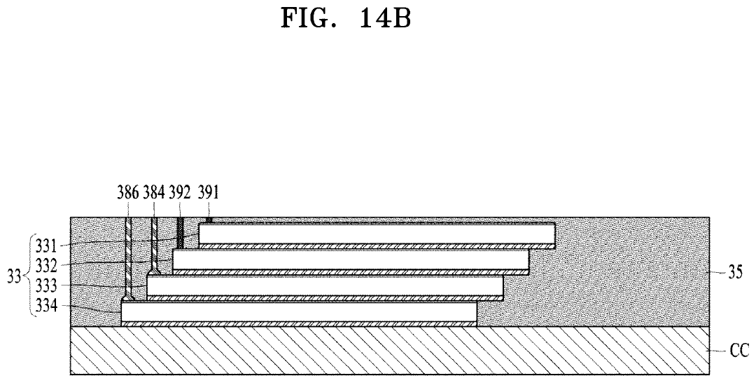

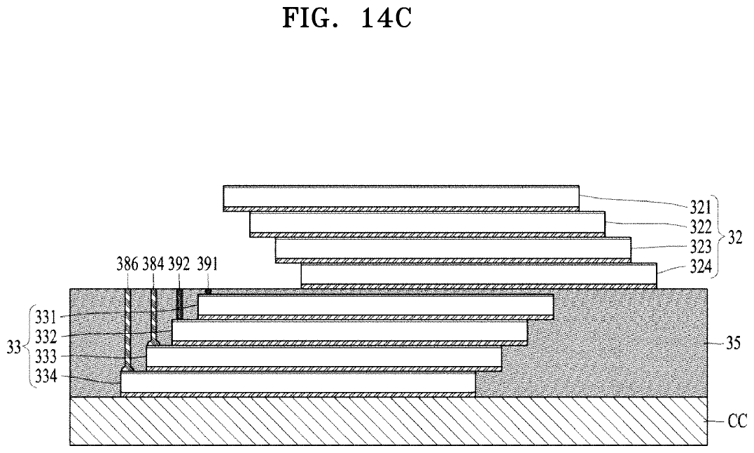

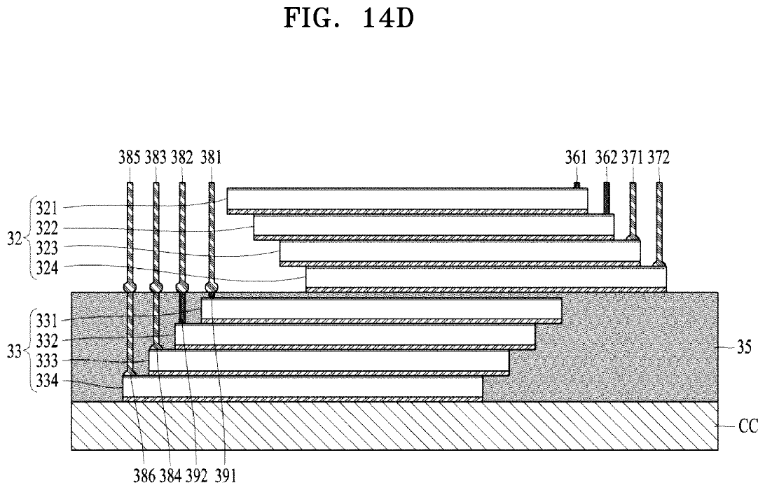

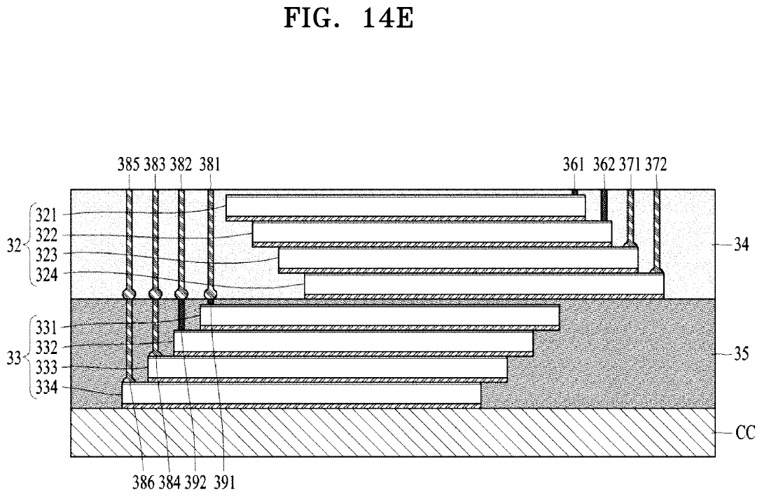

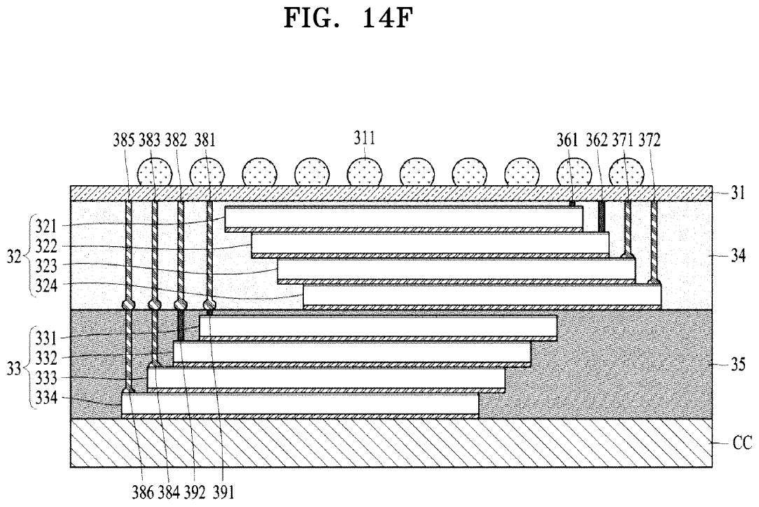

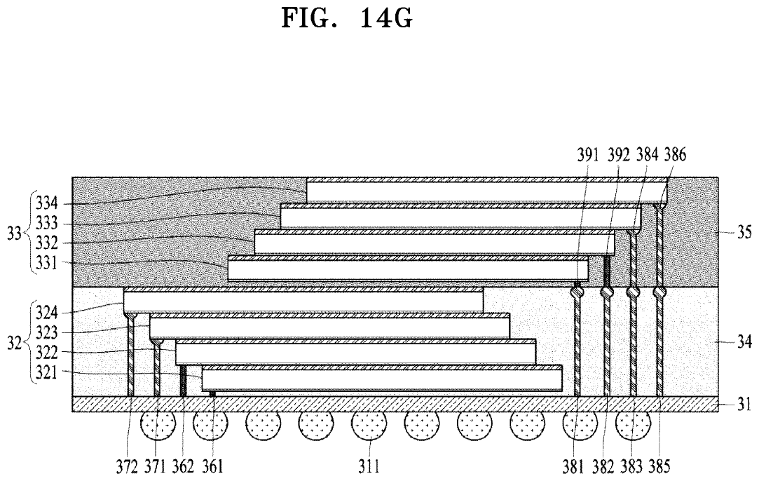

FIGS. 14A to 14G illustrate sequential operations of a method of manufacturing a semiconductor package including eight semiconductor chips according to an embodiment.

Referring to FIG. 14A, a (2-4)-th semiconductor chip 334, a (2-3)-th semiconductor chip 333, a (2-2)-th semiconductor chip 332, and a (2-1)-th semiconductor chip 331 of a second semiconductor chip group 33 may be stacked in a staircase shape on a carrier CC. Subsequently, one end of a (2-6)-th wire 386 may be directly connected to the (2-4)-th semiconductor chip 334, and one end of a (2-4)-th wire 384 may be directly connected to the (2-3)-th semiconductor chip 333. One end of a (2-2)-th bump 392 may be directly connected to the (2-2)-th semiconductor chip 332, and one end of a (2-1)-th bump 391 may be directly connected to the (2-1)-th semiconductor chip 331. For example, the (2-2)-th bump 392 may be an elevated pillar bump. For example, the elevated pillar bump may be formed by copper electroplating and solder reflow.

Referring to FIG. 14B, a second molding member 35 surrounding the second semiconductor chip group 33 may be formed. Here, another end of the (2-1)-th bump 391, another end of the (2-2)-th bump 392, another end of the (2-4)-th wire 384, and another end of the (2-6)-th wire 386 may be exposed to an outer surface of the second molding member 35.

Referring to FIG. 14C, a (1-4)-th semiconductor chip 324, a (1-3)-th semiconductor chip 323, a (1-2)-th semiconductor chip 322, and a (1-1)-th semiconductor chip 321 may be sequentially stacked in a staircase shape on an area adjacent to the second semiconductor chip group 33 and the second molding member 35. A first semiconductor chip group 32 including the (1-1)-th semiconductor chip 321, the (1-2)-th semiconductor chip 322, the (1-3)-th semiconductor chip 323, and the (1-4)-th semiconductor chip 324 may be formed.

Referring to FIG. 14D, one end of a (1-2)-th wire 372 may be directly connected to the (1-4)-th semiconductor chip 324, and one end of a (1-1)-th wire 371 may be directly connected to the (1-3)-th semiconductor chip 323. One end of a (1-2)-th bump 362 may be directly connected to the (1-2)-th semiconductor chip 322, and one end of a (1-1)-th bump 361 may be directly connected to the (1-1)-th semiconductor chip 321. For example, the (1-2)-th bump 362 may be an elevated pillar bump.

One end of a (2-5)-th wire 385 may be directly connected to the other end of the (2-6)-th wire 386, and one end of a (2-3)-th wire 383 may be directly connected to the other end of the (2-4)-th wire 384. One end of a (2-2)-th wire 382 may be directly connected to the other end of the (2-2)-th bump 392, and one end of a (2-1)-th wire 381 may be directly connected to the other end of the (2-1)-th bump 391.

Referring to FIG. 14E, a first molding member 34 surrounding the first semiconductor chip group 32 may be formed. Here, another end of the (1-1)-th bump 361, another end of the (1-2)-th bump 362, another end of the (1-1)-th wire 371, another end of the (1-2)-th wire 372, another end of the (2-1)-th wire 381, another end of the (2-2)-th wire 382, another end of the (2-3)-th wire 383, and another end of the (2-5)-th wire 385 may be exposed to an outer surface of the first molding member 34.

Referring to FIG. 14F, the other end of the (1-1)-th bump 361, the other end of the (1-2)-th bump 362, the other end of the (1-1)-th wire 371, the other end of the (1-2)-th wire 372, the other end of the (2-1)-th wire 381, the other end of the (2-2)-th wire 382, the other end of the (2-3)-th wire 383, and the other end of the (2-5)-th wire 385 may be brought into contact with one surface of a redistribution layer 31. Subsequently, a connection terminal 311 may be formed on another surface of the redistribution layer 31.

Referring to FIG. 14G, the carrier CC may be separated from a semiconductor package 3C, and the semiconductor package 3C may be rotated such that the redistribution layer 31 may face downward.

According to the embodiments of the invention, a maximum length of a wire connecting a semiconductor chip and a redistribution layer may be maintained to be ½ or less of a total height of a maximum semiconductor package, and thus wire sweeping may be effectively prevented. In addition, using a relatively short wire may be advantageous in forming fine-pitch wiring.

Furthermore, a semiconductor package according to an embodiment may have a multi-layer molding structure to minimize an overhang structure during a manufacturing process of the semiconductor package. Accordingly, a molding process may be performed without die cracks when an interconnector is formed.

In addition, a semiconductor package according to an embodiment may implement a large-capacity memory stack structure at a relatively low cost, and a thin semiconductor package may be implemented.

While the embodiments are described in connection with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

1. A semiconductor package comprising:
a package substrate; and
a first plurality of semiconductor chips disposed on the package substrate,
wherein a closest semiconductor chip of the first plurality of semiconductor chips to the package substrate is connected to the package substrate by a first bump, and
wherein a farthest semiconductor chip of the first plurality of semiconductor chips from the package substrate is connected to the package substrate by a first wire, and
the closest and farthest semiconductor chips perform the same function and have the same size as each other.

2. The semiconductor package of claim 1, further comprising:
a second plurality of semiconductor chips disposed on the first plurality of semiconductor chips,
wherein a closest semiconductor chip of the second plurality of semiconductor chips to the package substrate is connected to the package substrate by a second bump and a second wire, and
wherein a farthest semiconductor chip of the second plurality of semiconductor chips from the package substrate is connected to the package substrate by a first plurality of wires.

3. The semiconductor package of claim 2, further comprising:
a first molding layer surrounding the first plurality of semiconductor chips; and
a second molding layer surrounding the second plurality of semiconductor chips.

4. The semiconductor package of claim 3,
wherein the first plurality of semiconductor chips comprises a first semiconductor chip and a second semiconductor chip sequentially stacked on an area adjacent to the package substrate, and
wherein the first semiconductor chip is connected to the package substrate by a second bump, and the second semiconductor chip is connected to the package substrate by a third wire.

5. The semiconductor package of claim 4,
wherein the second plurality of semiconductor chips comprises a third semiconductor chip and a fourth semiconductor chip sequentially stacked on an area adjacent to the first plurality of semiconductor chips,
wherein the third semiconductor chip is connected to the package substrate by a fourth wire extending within the first molding layer and a third bump extending within the second molding layer, and
wherein the fourth semiconductor chip is connected to the package substrate by a fifth wire extending within the first molding layer and a sixth wire extending within the second molding layer.

6. The semiconductor package of claim 5,
wherein the semiconductor chips of the first plurality of semiconductor chips are sequentially stacked in a staircase shape in a direction from a first side of the semiconductor package toward a second side of the semiconductor package, and
wherein the semiconductor chips of the second plurality of semiconductor chips are sequentially stacked in a staircase shape in a direction from the second side toward the first side.

7. The semiconductor package of claim 6,
wherein the second bump is disposed on the first side, between the first side and the second side, or on the second side, and
wherein the third wire is disposed on the second side.

8. The semiconductor package of claim 7,
wherein the fourth wire and the third bump are disposed on the first side, and
wherein the fifth wire and the sixth wire are disposed on the first side.

9. The semiconductor package of claim 5,
wherein the semiconductor chips of the first plurality of semiconductor chips and the semiconductor chips of the second plurality of semiconductor chips are sequentially stacked in a staircase shape in a direction from a first side of the semiconductor package toward a second side of the semiconductor package, or a direction from the second side toward the first side.

10. The semiconductor package of claim 9,
wherein the second bump is disposed on the first side, between the first side and the second side, or on the second side, and
wherein the third wire, the fourth wire, the third bump, the fifth wire, and the sixth wire are disposed on the second side.

11. The semiconductor package of claim 9,
wherein the second bump is disposed on the first side, between the first side and the second side, or on the second side, and
wherein the third wire, the fourth wire, the third bump, the fifth wire, and the sixth wire are disposed on the first side.

12. The semiconductor package of claim 3,
wherein the first plurality of semiconductor chips comprises a first semiconductor chip, a second semiconductor chip, a third semiconductor chip, and a fourth semiconductor chip sequentially stacked on an area adjacent to the package substrate, and
wherein the first semiconductor chip is connected to the package substrate by a second bump, the second semiconductor chip is connected to the package substrate by a third bump, the third semiconductor chip is connected to the package substrate by a third wire, and the fourth semiconductor chip is connected to the package substrate by a fourth wire.

13. The semiconductor package of claim 12,
wherein the second plurality of semiconductor chips comprises a fifth semiconductor chip, a sixth semiconductor chip, a seventh semiconductor chip, and an eighth semiconductor chip sequentially stacked on an area adjacent to the first plurality of semiconductor chips, and
wherein the fifth semiconductor chip is connected to the package substrate by a fifth wire extending within the first molding layer and a fourth bump extending within the second molding layer, the sixth semiconductor chip is connected to the package substrate by a sixth wire extending within the first molding layer and a fifth bump extending within the second molding layer, the seventh semiconductor chip is connected to the package substrate by a seventh wire extending within the first molding layer and a eighth wire extending within the second molding layer, and the eighth semiconductor chip is connected to the package substrate by a ninth wire extending within the first molding layer and a tenth wire extending within the second molding layer.

14. The semiconductor package of claim 13, wherein
the semiconductor chips of the first plurality of semiconductor chips are sequentially stacked in a staircase shape in a direction from a first side of the semiconductor package toward a second side of the semiconductor package, and the semiconductor chips of the second plurality of semiconductor chips are sequentially stacked in a staircase shape in a direction from the second side toward the first side, or
the semiconductor chips of the first plurality of semiconductor chips and the semiconductor chips of the second plurality of semiconductor chips are sequentially stacked in a staircase shape in the direction from the first side to the second side or in a direction from the second side to the first side.

15.-20. (canceled)

21. A semiconductor package comprising:
a package substrate;
a first plurality of semiconductor chips disposed on the package substrate;
a second plurality of semiconductor chips disposed on the first plurality of semiconductor chips, the second plurality of semiconductor chips including a first semiconductor chip;
a first molding layer disposed on the package substrate, the first molding layer surrounding the first plurality of semiconductor chips;
a second molding layer disposed on the first molding layer, the second molding layer surrounding the second plurality of semiconductor chips;
a first bump formed on the first semiconductor chip; and
a first wire formed on the package substrate,
wherein the first bump and the first wire are in contact with each other, and
wherein an interface between the first bump and the first wire is aligned to an interface between the first and second molding layers.

22. The semiconductor package of claim 21, further comprising:
a second wire formed on the package substrate; and
a third wire being in contact with the second wire,
wherein the second plurality of semiconductor chips further includes a second semiconductor chip,
wherein the third wire is formed on the second semiconductor chip, and
wherein an interface between the second and third wire is aligned to the interface between the first and second molding layers.

23. The semiconductor package of claim 21, further comprising:
a second wire formed on the package substrate; and
a second bump being in contact with the second wire,
wherein the second plurality of semiconductor chips further includes a second semiconductor chip,
wherein the second bump is formed on the second semiconductor chip, and
wherein an interface between the second bump and the second wire is aligned to the interface between the first and second molding layers.

24. The semiconductor package of claim 23,
wherein in a height of the second bump is greater than a height of the first bump.

25. The semiconductor package of claim 21,
wherein the first wire includes an end portion and an elongated portion, and a width of the end portion is greater than a width of the elongated portion, and
wherein the end portion is in contact with the first bump.
